(19) United States
(12) Patent Application Publication
(10) Pub. No.: US 2019/0064216 A1
(43) Pub. Date: Feb. 28, 2019

(54) Probe Card System Having A Dielectric Fluid Dispenser

(71) Applicant: Keithley Instruments, LLC, Solon, OH (US)

(72) Inventors: Vladimir V. Genkin, Westfield Center, OH (US); Alexander N. Pronin, Twinsburg, OH (US); Joseph A. Peters, Cuyahoga Falls, OH (US)

(73) Assignee: Keithley Instruments, LLC, Solon, OH (US)

(21) Appl. No.: 15/687,351

(22) Filed: Aug. 25, 2017

(51) Int. Cl. G01R 1/067; B05C 5/02; G01R 31/28

(52) U.S. Cl. CPC G01R 1/06783; B05C 5/0287; G01R 31/2831; B05C 5/0237

(57) ABSTRACT

A system for testing an integrated-circuit wafer includes a probe card and a dispenser assembly. The probe card includes a circuit board and a probe needle coupled to the circuit board. The dispenser assembly is coupled to the probe card and is configured to deliver a metered amount of dielectric fluid to the tip of the probe needle. Methods are also disclosed.

### TECHNICAL FIELD

This disclosure is directed to a system and method for testing integrated-circuit wafers with a probe card.

### BACKGROUND

During fabrication of a semiconductor device, electronic circuits are created on a semiconductor wafer, and the wafer is then diced into individual chips. Before dicing, the integrated circuits are generally subjected to electrical tests to determine if the circuits function properly. Typically, the wafer is mounted, such as by vacuum mounting, to a wafer chuck of a machine called a wafer prober. And the wafer is brought into contact with one or more probe needles of a probe card. In this way, an electrical connection is made between contact pads on the wafer and the tips of the probe needles, allowing the integrated circuit to be tested for proper electrical function.

Due to the small distances and high voltages that might exist during the electrical tests of a semiconductor wafer, dielectric breakdown might be a problem.

Embodiments of the disclosed technology address shortcomings in the prior art.

### BRIEF DESCRIPTION OF THE DRAWINGS

FIG. 1 is a sectional, perspective view of a probe card, according to embodiments.

FIG. 2 is a front view of the probe card of FIG. 1.

FIG. 3 is a hydraulic schematic of portions of a dispenser assembly utilizing a peristaltic pump, according to embodiments.

FIG. 4 is a hydraulic schematic of portions of a dispenser assembly utilizing a gas-pressurized liquid pump, according to embodiments.

FIG. 5 is a flowchart showing a method of using a probe card to test an integrated circuit, according to embodiments.

### DETAILED DESCRIPTION

As described herein, embodiments of the invention are directed to novel configurations of a probe card for testing integrated-circuit wafers. In embodiments, a dispenser assembly is coupled to the probe card, and the dispenser assembly is configured to deliver a metered amount of dielectric fluid to the tip of the probe needle. This can help reduce or eliminate arcing during electrical testing of a semiconductor wafer. In embodiments, the metered amount of dielectric fluid is several drops or less localized to the area of the tip of the probe needle. Accordingly, the dielectric fluid may evaporate in a short period of time and without leaving residue on the wafer under test. Also, when compared to existing systems that fully bathe the wafer in dielectric fluid, the localized, relatively small volume of dielectric fluid (several drops or less, as noted) also allows the wafer to be exchanged more frequently, permits shorter test cycle times, and enables the system to be used to test wafers that cannot be fully submerged in fluid.

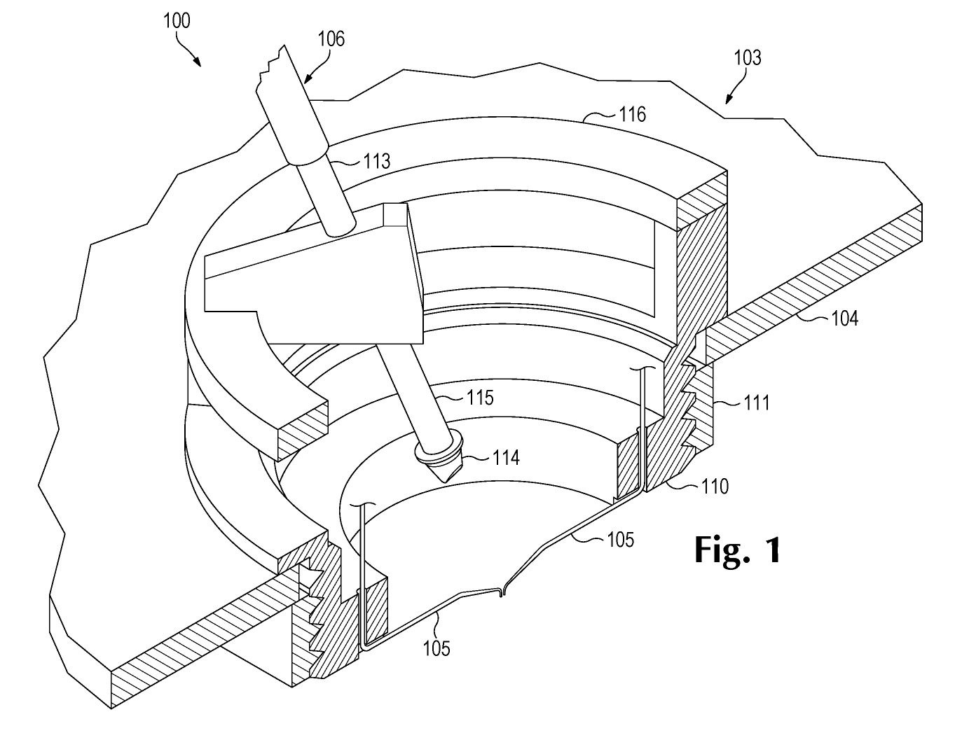

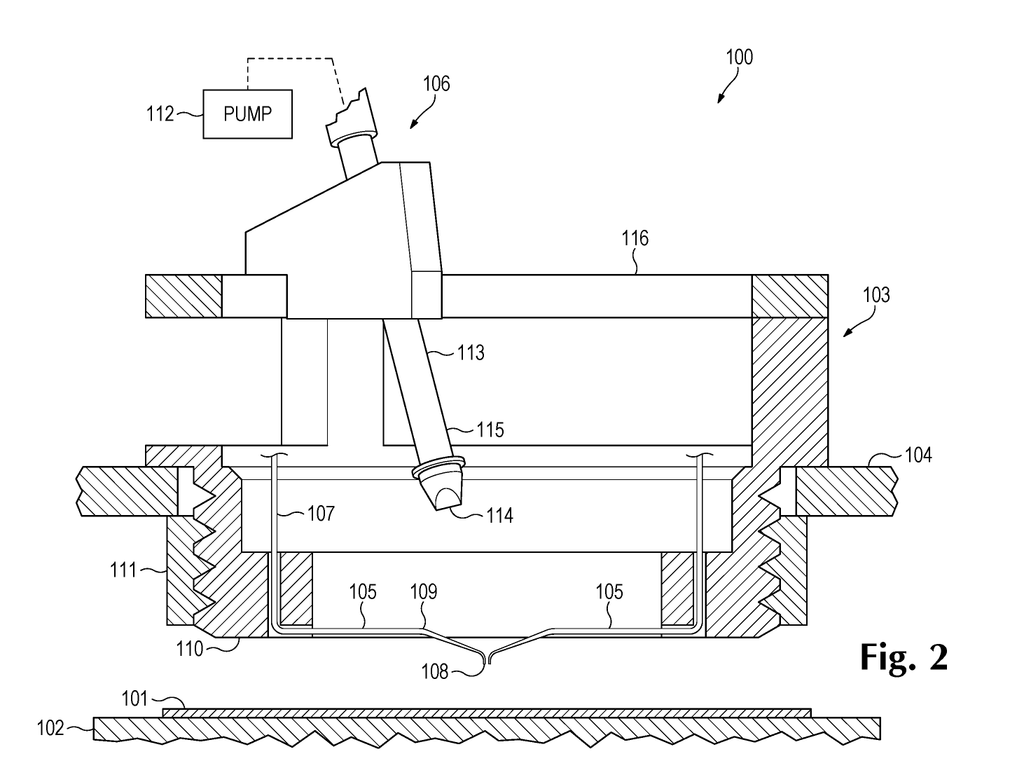

FIG. 1 is a sectional, perspective view showing portions of a probe card, according to embodiments of the invention. FIG. 2 is a front view of the probe card of FIG. 1. As illustrated in FIGS. 1 and 2, a system 100 for testing an integrated-circuit wafer 101 held by a wafer chuck 102 of a wafer prober may include a probe card 103. The probe card 103 may include a printed circuit board 104, a probe needle 105, and a dispenser assembly 106.

The probe needle 105 typically provides an electrical connection between the probe card 103 and the wafer 101 under test. As illustrated, the probe needle 105 may be coupled to the circuit board 104 at a first end 107 of the probe needle 105, and have a tip 108 of the probe needle 105 at an opposite, second end 109 of the probe needle 105.

The probe needle 105 may be made from, for example, wire, such as tungsten wire, having a diameter of about 25 mil. As known in the art, a mil is 0.001 of an inch (which is about 0.025 mm). Thus, 25 mil is 0.025 inches (about 0.635 mm). At the tip 108 of the probe needle 105, the wire diameter may be reduced to about 5 microns by, for example, chemically etching the wire. As known in the art, a micron is about 0.000039 inches. Thus, 5 microns is about 0.0002 inches. The overall length of the probe needle 105, from the first end 107 of the probe needle to the tip 108 of the probe needle, is typically around 1.25 inches, although other lengths may be suitable.

The probe card 103 may include a probe needle insert 110 coupled to the circuit board 104, and the probe needle 105 may be secured to the probe needle insert 110. As illustrated, the probe needle insert 110 may fit within a hole or slot in the circuit board 104, and an insert nut 111 may be used to secure the probe needle insert 110 to the circuit board 104.

The dispenser assembly 106 is coupled to the probe card 103 and is configured to deliver a metered amount of dielectric fluid to the tip 108 of the probe needle 105. For example, the dispenser assembly 106 may include a pump 112 to propel dielectric fluid toward the tip 108 of the probe needle 105. As illustrated in FIGS. 1 and 2, the dispenser assembly 106 may include a liquid conduit 113 and a dispenser valve 114 at an end 115 of the liquid conduit 113. The dispenser valve 114 is configured to deliver the metered amount of dielectric fluid. The dispenser valve 114 may be, for example, a duckbill valve. Accordingly, the dispenser assembly 106 is positioned proximate to the tip 108 of the probe needle 105 to allow dielectric fluid to drip from the dispenser assembly 106 under the force of gravity or squirt from the dispenser assembly 106 under pressure.

The dispenser assembly 106 may also include a dispenser frame 116 configured to couple the liquid conduit 113 to the probe card 103. The dispenser frame 116 may secure the dispenser valve 114 relative to the tip 108 of the probe needle 105, thus positioning the dispenser assembly 106 proximate to the tip 108 of the needle as discussed above. In embodiments having a probe needle insert 110, the dispenser frame 116 may be secured to the probe needle insert 110. The dispenser frame 116 may, for example, have an arcuate or circular planform and a rectangular cross-section, such as illustrated in FIGS. 1 and 2.

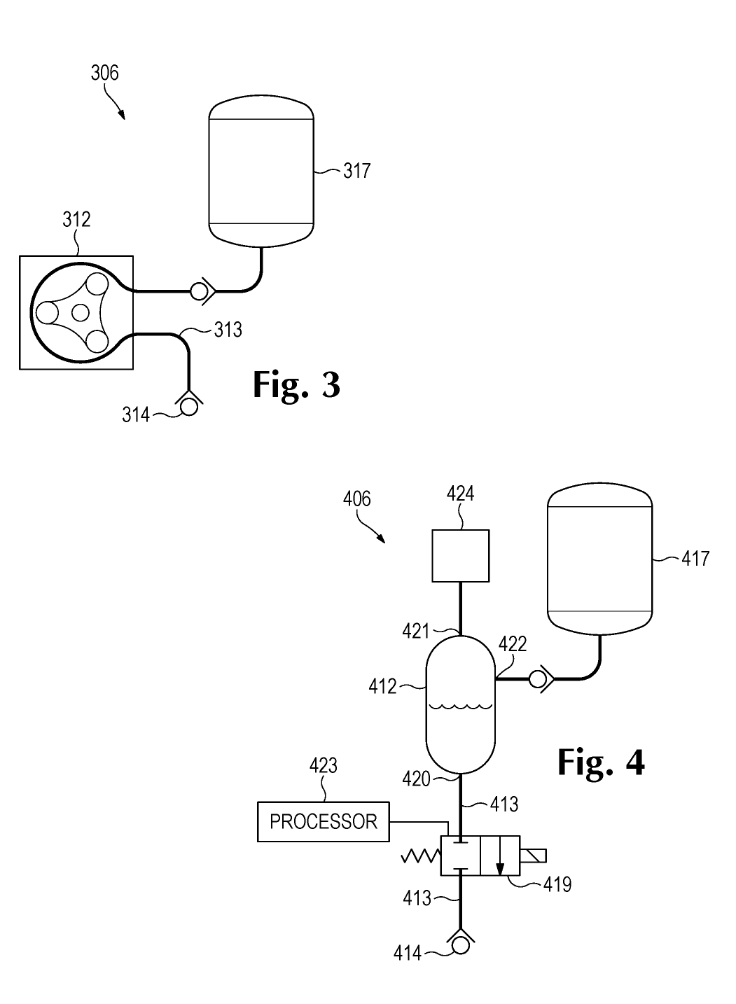

As noted above, the dispenser assembly 106 may include a pump 112 to propel dielectric fluid toward the tip 108 of the probe needle 105. The pump 112 of may be, for example, a peristaltic pump or a gas-pressurized liquid pump, as discussed below for FIGS. 3 and 4.

The dispenser assembly 106 may include a reservoir configured to hold a volume of dielectric fluid, such as the reservoir 317 or the reservoir 417 discussed below for FIGS. 3 and 4, respectively. In embodiments, the dispenser assembly 106 may lack a pump 112, and the reservoir may be connected directly to the liquid conduit 113, which terminates with the dispenser valve 114. In such embodiments, the position of the reservoir relative to the dispenser valve 114 provides the force to propel the dielectric fluid through the liquid conduit 113 and toward the dispenser valve 114. For example, the position of the reservoir relative to the dispenser valve 114 may provide elevation head to the dispenser assembly 106.

In embodiments, the dispenser assembly 106 may lack a dispenser valve 114. In such embodiments, the action of the pump 112 may deliver the desired volume of dielectric fluid through the liquid conduit 113 and out the end 115 of the liquid conduit 113.

FIG. 3 is a hydraulic schematic of portions of a dispenser assembly, according to embodiments, having a peristaltic pump. As illustrated in FIG. 3, a dispenser assembly 306 system may include a reservoir 317, a peristaltic pump 312, and a dispenser valve 314. A liquid conduit 313 connects the peristaltic pump 312 and the dispenser valve 314.

The reservoir 317 is configured to hold a volume of dielectric fluid. Preferably, the dielectric fluid has a dielectric strength of at least 12 kV per 0.1 inch (about 4,700 kV/m). More preferably, the dielectric fluid has a dielectric strength of at least 25 kV per 0.1 inch (about 9,800 kV/m). Even more preferably, the dielectric fluid has a dielectric strength of at least 38 kV per 0.1 inch (about 15,000 kV/m). The dielectric fluid may be, for example, the FLUORINERT® liquid composition provided by 3M Company of St. Paul, Minn., which has a dielectric strength greater than 40 kV per 0.1 inch (about 16,000 kV/m).

The dispenser valve 314 allows dielectric fluid to flow from the liquid conduit 313. As noted above, the dispenser valve 314 may be a duckbill valve.

The peristaltic pump 312 may be powered, for example, by a power source providing a DC impulse, such as about every ten milliseconds or faster. When the peristaltic pump 312 receives a DC impulse or other signal to begin pumping, the peristaltic pump 312 moves a volume of dielectric fluid through the liquid conduit 313. This movement of fluid builds up pressure in the liquid conduit 313. When the pressure in the liquid conduit 313 is equal to the cracking pressure of the dispenser valve 314, the dispenser valve 314 opens, expelling a small amount of dielectric fluid onto the tip 108 of the probe needle 105. Preferably, the cracking pressure of the dispenser valve 314 is between about 1.5 mbar and about 30 mbar. More preferably, the cracking pressure is between about 3 mbar and about 24 mbar. Even more preferably, the cracking pressure is between about 5 mbar and about 17 mbar.

As noted above, the dielectric fluid may drip from the dispenser valve 314 under the force of gravity or squirt from the dispenser valve 314 under the pressure generated within the liquid conduit 313. This expelled fluid encapsulates the test area in electrically non-conductive volume (the drop of dielectric fluid) before high voltage is applied during electrical testing of the wafer 101 under test.

Preferably, the dispenser valve 314, the liquid conduit 313, or the peristaltic pump 312, or any two or three of them, are configured such that the small amount of dielectric fluid that is expelled is several drops or less. For example, the dispenser valve 314 may be configured to have a cracking pressure sufficient to release the desired amount of liquid and then reclose. The liquid conduit 313 may be configured to hold a volume of liquid such that, upon release of the desired amount of dielectric fluid from the dispenser valve 314, the pressure within the liquid conduit 313 drops below the cracking pressure of the dispenser valve 314, causing the dispenser valve 314 to close again. Also, the peristaltic pump 312 may be configured to move a volume of dielectric fluid that corresponds to the amount of liquid desired to be released by the dispenser valve 314. For example, the volume of dielectric fluid moved by the pump 112 may be substantially equal to the amount of liquid desired to be released by the dispenser valve 314.

Preferably, the expelled volume, or the amount of liquid desired to be released by the dispenser valve 314, is between about 2 cubic millimeters and about 14 cubic millimeters. More preferably, the expelled volume is between about 4 cubic millimeters and about 12 cubic millimeters. Even more preferably, the expelled volume is between 6 cubic millimeters and 10 cubic millimeters.

The amount expelled is preferably as a single drop of dielectric fluid having the volume noted. Also, the dispenser assembly 306 preferably is configured to rapidly deliver the expelled volume at a rate between about 20 milliseconds and about 200 milliseconds. More preferably, the dispenser assembly 306 is configured to deliver the expelled volume at a rate between about 35 milliseconds and about 175 milliseconds. Even more preferably, the dispenser assembly 306 is configured to deliver the expelled volume at a rate between 50 milliseconds and 150 milliseconds. For example, the DC-impulse power source for the peristaltic pump 312 may be tuned to provide an impulse signal at the desired time interval, thereby producing one drop of the desired volume per impulse at the intervals noted. Other configurations could also be used to provide the desired volume of dielectric fluid at the desired rate.

FIG. 4 is a hydraulic schematic of portions of a dispenser assembly, according to embodiments, having a gas-pressurized liquid pump. As illustrated in FIG. 4, a dispenser assembly 406 may include a reservoir 417, a gas-pressurized liquid pump 412, a control valve 419, and a dispenser valve 414. A liquid conduit 413 connects the gas-pressurized liquid pump 412, the control valve 419, and the dispenser valve 414.

The reservoir 417 is configured to hold a volume of dielectric fluid having a dielectric strength as discussed above for FIG. 3. The dispenser valve 414 allows dielectric fluid to flow from the liquid conduit 413 and may be a duckbill valve.

As used in this disclosure, a gas-pressurized liquid pump 412 is a vessel partially filled with liquid and partially filled with pressurized gas. The gas may be, for example, air or nitrogen. The force on the liquid created by the pressurized gas causes the liquid to exit the vessel, such as through an outlet 420. The vessel may also include an inlet 421 for receiving the pressurized gas from a pressurized-gas source 424 as well as an inlet 422 for the liquid.

The control valve 419 may be along the liquid conduit 413, between the gas-pressurized liquid pump 412 and the dispenser valve 414. The control valve 419 may have a first condition allowing dielectric fluid to flow from the pump 412 through the liquid conduit 413 and a second condition blocking the flow of dielectric fluid through the liquid conduit 413. Preferably, the control valve 419 operates by computerized numerical control (CNC). Accordingly, the control valve 419 may be a normally-closed, spring-offset, solenoid-operated, two-way valve.

Hence, in operation, the control valve 419 may be normally closed. The control valve 419 may receive a signal from a processor 423 to operate. In response, the control valve 419, may open to allow dielectric fluid to move through the liquid conduit 413. This movement of fluid builds up pressure in the liquid conduit 413. When the pressure in the liquid conduit 413 is equal to the cracking pressure of the dispenser valve 414, the dispenser valve 414 opens, expelling a small amount of dielectric fluid on the tip 108 of the probe needle 105. The cracking pressure of the dispenser valve 414 may be as above for the dispenser valve 314 of FIG. 3. As noted above, the dielectric fluid may drip from the dispenser valve 414 under the force of gravity or squirt from the dispenser valve 414 under the pressure generated within the liquid conduit 413. This encapsulates the test area in an electrically non-conductive volume (the drop of dielectric fluid) before high voltage is applied during electrical testing of the wafer 101 under test.

Preferably, the dispenser valve 414, the liquid conduit 413, and the control valve 419, or any two or three of them, are configured such that the small amount of dielectric fluid that is expelled is several drops or less. For example, the dispenser valve 414 and the liquid conduit 413 may be configured as discussed above for FIG. 3. The control valve 419 may be configured to, once open, allow to pass only a volume of dielectric fluid that corresponds to the amount of liquid desired to be released by the dispenser valve 414. For example, the volume of dielectric fluid allowed through the control valve 419 may be substantially equal to the amount of liquid desired to be released by the dispenser valve 414.

The preferred expelled volume, or the amount of liquid desired to be released by the dispenser valve 414, are as discussed above for FIG. 3. Also, the amount expelled is preferably as a single drop of dielectric fluid having the volume noted in the discussion of FIG. 3. As above, the dispenser assembly 406 preferably is configured to deliver the expelled volume at a rate between about 20 milliseconds and about 200 milliseconds. More preferably, the dispenser assembly 406 is configured to deliver the expelled volume at a rate between about 35 milliseconds and about 175 milliseconds. Even more preferably, the dispenser assembly 406 is configured to deliver the expelled volume at a rate between 50 milliseconds and 150 milliseconds. For example, processor 423 may be tuned to provide an operate signal to the control valve 419 at the desired time interval, thereby producing one drop of the desired volume per operate signal from the processor at the intervals noted. Other configurations could also be used to provide the desired volume of dielectric fluid at the desired rate.

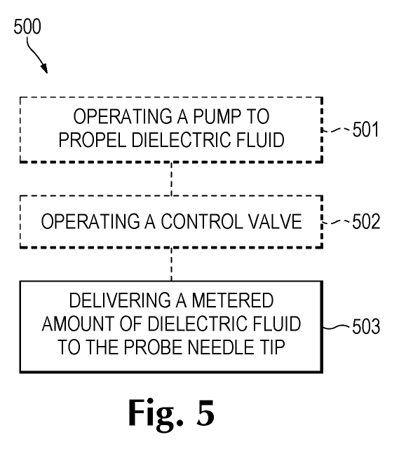

FIG. 5 is a flowchart showing portions of a method of using a probe card to test an integrated circuit, according to embodiments. As illustrated in FIG. 5, a method 500 of using a probe card to test an integrated-circuit wafer, the probe card having a probe needle with a tip, includes delivering 503, with a dispenser assembly coupled to the probe card, a metered amount of dielectric fluid to the tip of the probe needle. The delivering may also include operating 502 a control valve along a liquid conduit secured to the probe card.

In embodiments, the delivering is delivering a drop of dielectric fluid to the tip of the probe needle. Preferably, the drop has a volume of six to ten cubic millimeters, although the drop volume could be within the preferred ranges discussed above for FIG. 3. In embodiments, the delivering further includes delivering the drop at a rate of about one drop per second.

The method 500 may also include operating 501 a pump to propel dielectric fluid in a liquid conduit toward the tip of the probe needle.

The probe card, probe needle, dispenser assembly, control valve, liquid conduit, and pump of the method 500 may be as described above for FIGS. 1-4.

Accordingly, embodiments of the disclosed technology help reduce or eliminate arcing during electrical testing of a semiconductor wafer by placing a localized, relatively small volume of dielectric fluid at the tip of the probe needle. Hence, embodiments may allow the wafer to be exchanged more frequently when compared to existing systems that fully bathe the wafer in dielectric fluid. Specifically, systems that require the wafer to be fully submerged also require that the wafer be slowly submerged and slowly withdrawn from the liquid bath during the test cycle to prevent splashes or spills onto the surrounding components of the wafer prober. Embodiments of the disclosed system, however, may allow the wafer under test to be placed into and withdrawn from the wafer prober at standard speed, meaning the typical rate for wafer probers that do not use a liquid bath. For the same reason, embodiments of the disclosed system may permit shorter test cycle times since the wafer does not have to be placed in the liquid bath. Instead, the disclosed system preferably takes 200 milliseconds or less to apply the localized, relatively small volume of dielectric fluid at the tip of the probe needle, and the dielectric fluid may evaporate after the electrical test is completed. Likewise, the disclosed system may be used to test wafers that cannot be fully submerged in fluid.

### EXAMPLES

Illustrative examples of the disclosed technologies are provided below. An embodiment of the technologies may include one or more, and any combination of, the examples described below.

Example 1 includes a system for testing an integrated-circuit wafer. The system comprises a probe card and a dispenser assembly. The probe card comprises a circuit board and a probe needle coupled to the circuit board at a first end of the probe needle. The probe needle has a tip of the probe needle at an opposite, second end of the probe needle. The dispenser assembly is coupled to the probe card, and the dispenser assembly is configured to deliver a metered amount of dielectric fluid to the tip of the probe needle.

Example 2 includes the system of Example 1, in which the dispenser assembly comprises a pump configured to propel dielectric fluid toward the tip of the probe needle.

Example 3 includes the system of Example 2, in which the pump is a peristaltic pump.

Example 4 includes the system of Example 2, in which the pump is a gas-pressurized liquid pump.

Example 5 includes the system of any of Examples 2-4, in which the dispenser assembly further comprises a liquid conduit and a control valve along the liquid conduit. The liquid conduit extends from an outlet side of the pump. The control valve has a first condition allowing dielectric fluid to flow from the pump through the liquid conduit and a second condition blocking dielectric fluid flow through the liquid conduit.

Example 6 includes the system of any of Examples 1-5, in which the dispenser assembly includes a reservoir configured to hold a volume of dielectric fluid.

Example 7 includes the system of any of Examples 1-6, in which the probe card further comprises a probe needle insert coupled to the circuit board, the probe needle being secured to the probe needle insert.

Example 8 includes the system of any of Examples 1-7, in which the dispenser assembly comprises a liquid conduit and a dispenser valve at an end of the liquid conduit and configured to deliver the metered amount of dielectric fluid.

Example 9 includes the system of Example 8, in which the dispenser assembly further comprises a dispenser frame configured to couple the liquid conduit to the probe card, the dispenser frame securing the dispenser valve relative to the tip of the probe needle.

Example 10 includes the system of any of Examples 1-9, in which the probe card further comprises a probe needle insert coupled to the circuit board.

Example 11 includes the system of Example 10, in which the probe needle and the dispenser frame are secured to the probe needle insert.

Example 12 includes the system of any of Examples 8-11, in which the dispenser valve is a duckbill valve.

Example 13 includes a method of using a probe card to test an integrated-circuit wafer, the probe card having a probe needle with a tip. The method comprises delivering, with a dispenser assembly coupled to the probe card, a metered amount of dielectric fluid to the tip of the probe needle.

Example 14 includes the method of Example 13, in which the method further comprises operating a pump to propel dielectric fluid in a liquid conduit toward the tip of the probe needle.

Example 15 includes the method of Example 13 or Example 14, in which the delivering the metered amount includes operating a control valve along a liquid conduit secured to the probe card.

Example 16 includes the method of any of Examples 13-15, in which the delivering the metered amount of dielectric fluid to the tip of the probe needle is delivering a drop of dielectric fluid to the tip of the probe needle.

Example 17 includes the method of Example 16, in which the delivering a drop of dielectric fluid to the tip of the probe needle further comprises delivering the drop at a rate between 50 milliseconds and 150 milliseconds.

Example 18 includes the method of Example 16, in which the delivering a drop of dielectric fluid to the tip of the probe needle is delivering a drop of dielectric fluid to the tip of the probe needle, the drop having a volume between 6 cubic millimeters and 10 cubic millimeters.

The previously described versions of the disclosed subject matter have many advantages that were either described or would be apparent to a person of ordinary skill. Even so, all of these advantages or features are not required in all versions of the disclosed apparatus, systems, or methods.

Additionally, this written description makes reference to particular features. It is to be understood that the disclosure in this specification includes all possible combinations of those particular features. For example, where a particular feature is disclosed in the context of a particular aspect or embodiment, that feature can also be used, to the extent possible, in the context of other aspects and embodiments.

Also, when reference is made in this application to a method having two or more defined steps or operations, the defined steps or operations can be carried out in any order or simultaneously, unless the context excludes those possibilities.

Furthermore, the term “comprises” and its grammatical equivalents are used in this application to mean that other components, features, steps, processes, operations, etc. are optionally present. For example, an article “comprising” or “which comprises” components A, B, and C can contain only components A, B, and C, or it can contain components A, B, and C along with one or more other components.

Although specific embodiments of the invention have been illustrated and described for purposes of illustration, it will be understood that various modifications may be made without departing from the spirit and scope of the invention. Accordingly, the invention should not be limited except as by the appended claims.

1. A system for testing an integrated-circuit wafer, the system comprising:
a probe card comprising a circuit board and a probe needle coupled to the circuit board at a first end of the probe needle, the probe needle having a tip of the probe needle at an opposite, second end of the probe needle; and
a dispenser assembly coupled to the probe card and configured to deliver a metered amount of dielectric fluid to the tip of the probe needle.

2. The system of claim 1, in which the dispenser assembly comprises a pump configured to propel dielectric fluid toward the tip of the probe needle.

3. The system of claim 2, in which the pump is a peristaltic pump.

4. The system of claim 2, in which the pump is a gas-pressurized liquid pump.

5. The system of claim 4, in which the dispenser assembly further comprises:
a liquid conduit extending from an outlet side of the pump; and
a control valve along the liquid conduit, the control valve having a first condition allowing dielectric fluid to flow from the pump through the liquid conduit and a second condition blocking dielectric fluid flow through the liquid conduit.

6. The system of claim 1, in which the dispenser assembly includes a reservoir configured to hold a volume of dielectric fluid.

7. The system of claim 1, in which the probe card further comprises a probe needle insert coupled to the circuit board, the probe needle being secured to the probe needle insert.

8. The system of claim 1, the dispenser assembly comprising:
a liquid conduit; and
a dispenser valve at an end of the liquid conduit and configured to deliver the metered amount of dielectric fluid.

9. The system of claim 8, the dispenser assembly further comprising a dispenser frame configured to couple the liquid conduit to the probe card, the dispenser frame securing the dispenser valve relative to the tip of the probe needle.

10. The system of claim 9, in which the probe card further comprises a probe needle insert coupled to the circuit board, the probe needle and the dispenser frame being secured to the probe needle insert.

11. The system of claim 8, in which the dispenser valve is a duckbill valve.

12. A method of using a probe card to test an integrated-circuit wafer, the probe card having a probe needle with a tip, the method comprising delivering, with a dispenser assembly coupled to the probe card, a metered amount of dielectric fluid to the tip of the probe needle.

13. The method of claim 12, further comprising operating a pump to propel dielectric fluid in a liquid conduit toward the tip of the probe needle.

14. The method of claim 12, in which the delivering the metered amount includes operating a control valve along a liquid conduit secured to the probe card.

15. The method of claim 12, in which the delivering the metered amount of dielectric fluid to the tip of the probe needle is delivering a drop of dielectric fluid to the tip of the probe needle.

16. The method of claim 15, in which the delivering a drop of dielectric fluid to the tip of the probe needle further comprises delivering the drop at a rate between 50 milliseconds and 150 milliseconds.

17. The method of claim 15, in which the delivering a drop of dielectric fluid to the tip of the probe needle is delivering a drop of dielectric fluid to the tip of the probe needle, the drop having a volume between 6 cubic millimeters and 10 cubic millimeters.
